(19) United States
(12) Patent Application Publication
(10) Pub. No.: US 2009/0105977 A1
(43) Pub. Date: Apr. 23, 2009

(54) TEST APPARATUS, SKEW MEASURING APPARATUS, DEVICE AND BOARD

(75) Inventors: YASUO FURUKAWA, TOKYO (JP); KOJI ASAMI, TOKYO (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/947,786

(22) Filed: Nov. 30, 2007

(30) Foreign Application Priority Data
Oct. 19, 2007 (JP) 2007-272999

(51) Int. Cl. G06F 19/00; G01R 29/26

(52) U.S. Cl. 702/69; 702/124

(57) ABSTRACT

There is provided a test apparatus for testing a device under test, which includes a plurality of drivers which output signals to the device under test, an output control section which controls the plurality of drivers to output a plurality of signals respectively, a calculating section which calculates skews of the plurality of signals output from the plurality of drivers respectively, based on a combination signal obtained by combining the plurality of signals, and an adjusting section which adjusts the timings to output signals to be output from the plurality of drivers, based on the skews.

### CROSS REFERENCE

The present application claims priority from a Japanese Patent Application No. 2007-272999 filed on Oct. 19, 2007, the contents of which are incorporated herein by reference.

### BACKGROUND

1. Technical Field

The present invention relates to a test apparatus, a skew measuring apparatus, a device, and a board. Particularly, the present invention relates to a test apparatus, a skew measuring apparatus, a device and a board for measuring skews of a plurality of signals output from a plurality of drivers.

2. Related Art

A test apparatus for testing a device under test such as a semiconductor device or the like is subjected to adjustment (skew adjustment) to make the phases of a plurality of test signals coincide at predetermined points (e.g., input terminals of the device under test) on transmission paths. For example, Unexamined Japanese Patent Application Publication No. 2001-183419 describes a test apparatus which is subjected to skew adjustment by an automatic contact maker, which brings its probe into contact with respective pins of a socket sequentially and adjusts any skews based on the phases of the signals detected by the probe.

Recent test apparatuses can simultaneously test more pins (channels) of a device under test than ever. For example, such a test apparatus can test pins of 2,000 channels at the same time. However, the larger the number of channels, the longer time the test apparatus requires for skew adjustment.

### SUMMARY

Hence, according to one aspect of the innovation included herein, an object is to provide a test apparatus, a skew measuring apparatus, a device, and a board which can solve the above-described problem. This object will be achieved by combinations of the features recited in the independent claims. Dependent claims define additional advantageous specific examples of the present invention.

That is, according to one exemplary test apparatus according to a first aspect relating to the innovation included herein, there is provided a test apparatus for testing a device under test, which includes: a plurality of drivers which output signals to the device under test; an output control section which controls the plurality of drivers to output a plurality of signals respectively; a calculating section which calculates skews of the plurality of signals output from the plurality of drivers respectively, based on a combination signal obtained by combining the plurality of signals; and an adjusting section which adjusts timings to output signals to be output from the plurality of drivers respectively, based on the skews.

According to one exemplary test apparatus according to a second aspect relating to the innovation included herein, there is provided a skew measuring apparatus for measuring skews of a plurality of signals output from a plurality of drivers, which includes: an output control section which controls the plurality of drivers to output a plurality of signals respectively; and a calculating section which calculates skews of the plurality of signals output from the plurality of drivers respectively, based on a combination signal obtained by combining the plurality of signals.

According to one exemplary device according to a third aspect relating to the innovation included herein, there is provided a device which is, instead of a device under test, mounted on a performance board, in measuring skews of a plurality of signals output from a plurality of drivers provided in a test apparatus for testing the device under test, the device including: a combining section which receives and combines together the plurality of signals which are from a plurality of signal output terminals of the performance board, the signal output terminals being interfaces to the device under test that exist on a plurality of transmission paths through which signals are transmitted from the plurality of drivers to the device under test.

According to one exemplary board according to a fourth aspect relating to the innovation included herein, there is provided a board which is, instead of a performance board on which a device under test is mounted, attached to a test head, in measuring skews of a plurality of signals output from a plurality of drivers provided in a test apparatus for testing the device under test, the board including: a combining section which receives and combines together the plurality of signals which are from a plurality of signal output terminals of the test head, the signal output terminals being interfaces to the performance board that exist on a plurality of transmission paths through which signals are transmitted from the plurality of drivers to the device under test.

The above summary of the invention is not intended to list all necessary features of the present invention, but sub-combinations of these features can also provide an invention.

### BRIEF DESCRIPTION OF THE DRAWINGS

FIG. 1 shows the configuration of a test apparatus 10 according to the present embodiment.

FIG. 2 shows one example of the configuration of a combining section 32 and one example of the configuration of a calculating section 34, together with a plurality of drivers 26.

FIG. 3 shows one example of a plurality of measurement signals output at different timings from each other.

FIG. 4 shows one example of the process flow of the calculating section 34 in a case where a plurality of measurement signals output at different timings from each other are output.

FIG. 5 shows one example of a plurality of measurement signals having frequencies different from each other.

FIG. 6 shows one example of the process flow of the calculating section 34 in a case where a plurality of measurement signals having frequencies different from each other are output.

FIG. 7 shows one example of a plurality of measurement signals having different code patterns from each other.

FIG. 8 shows a first example of the process flow of the calculating section 34 in a case where a plurality of measurement signals having different code patterns from each other are output.

FIG. 9 shows a second example of the process flow of the calculating section 34 in a case where a plurality of measurement signals having different code patterns from each other are output.

FIG. 10 shows a third example of the process flow of the calculating section 34 in a case where a plurality of measurement signals having different code patterns from each other are output.

FIG. 11 shows the configuration of the test apparatus 10 according to a first modification of the present embodiment.

FIG. 12 shows the configuration of the test apparatus 10 according to a second modification of the present embodiment.

FIG. 13 shows the configuration of the test apparatus 10 according to a third modification of the present embodiment.

FIG. 14 shows the configuration of the test apparatus 10 according to a fourth modification of the present embodiment.

### DESCRIPTION OF EXEMPLARY EMBODIMENTS

One aspect of the present invention will be explained below through an embodiment of the invention, but the embodiment below is not intended to limit the invention set forth in the claims or all combinations of the features explained in the embodiment are not necessarily essential to the means of solving provided by the present invention.

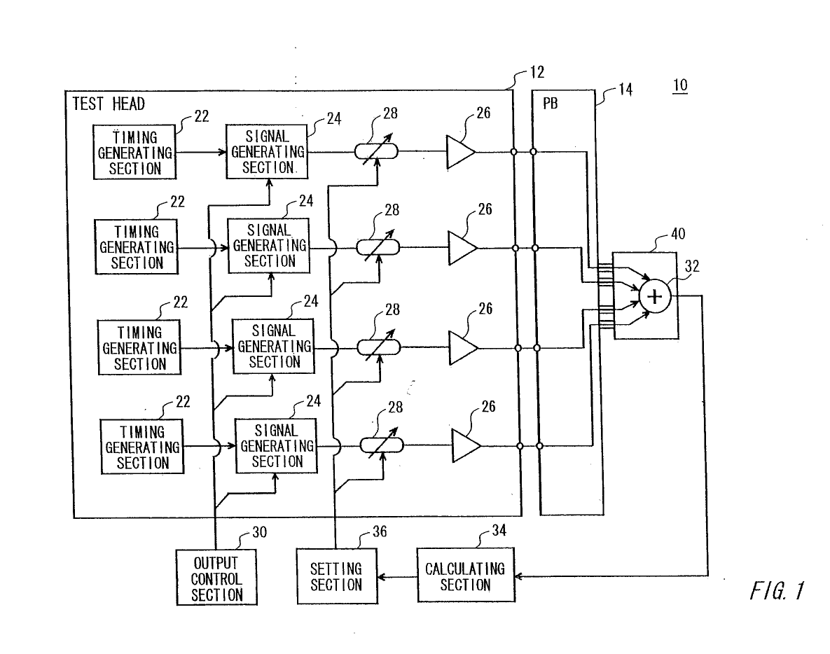

FIG. 1 shows the configuration of a test apparatus 10 according to the present embodiment. The test apparatus 10 includes a test head 12 and a performance board 14.

The test head 12 supplies a test signal to a device under test. The test head 12 receives a response signal output from the device under test in response to the test signal having been supplied thereto, and judges whether the device under test is a pass or a failure.

The performance board 14 is attached to the test head 12. The device under test is mounted on the performance board 14 while the performance board 14 is attached to the test head 12. The performance board 14 connects a plurality of pins of the device under test mounted thereon to a plurality of input/output terminals of the test head 12 through a plurality of transmission paths.

The test apparatus 10 further includes a plurality of timing generating sections 22, a plurality of signal generating sections 24, a plurality of drivers 26, a plurality of adjusting sections 28, an output control section 30, a combining section 32, a calculating section 34, and a setting section 36.

The plurality of timing generating sections 22 are provided in correspondence with a plurality of channels. The plurality of timing generating sections 22 are, for example, accommodated in the test head 12. Each timing generating section 22 generates a timing signal which is to be the reference for a test signal to be output to the transmission path of the corresponding channel.

The plurality of signal generating sections 24 are provided in correspondence with the plurality of channels. The plurality of signal generating sections 24 are, for example, accommodated in the test head 12. Each signal generating section 24 generates a test signal to be supplied to the device under test, based on the timing signal output from the timing generating section 22 of the corresponding channel.

The plurality of drivers 26 are provided in correspondence with the plurality of channels. The plurality of drivers 26 are, for example, accommodated in the test head 12. Each driver 26 outputs the test signal generated by the signal generating section 24 of the corresponding channel to the corresponding pin of the device under test through the transmission path of the corresponding channel.

The plurality of adjusting sections 28 are provided in correspondence with the plurality of channels. The plurality of adjusting sections 28 are, for example, accommodated in the test head 12.

Each adjusting section 28 has a skew adjusting amount set by the setting section 36. Each adjusting section 28 adjusts the timing at which the test signal of the corresponding channels is output. To be more specific, each adjusting section 28 changes (delays or accelerates) the timing to output the test signal of the corresponding channel from a designated timing by a time duration corresponding to the skew adjusting amount. For example, each adjusting section 28 may delay the timing signal by the time duration corresponding to the timing adjusting amount thereby to change the timing to output the test signal. Further, for example, each adjusting section 28 may add or subtract the skew adjusting amount to or from timing data indicating the designated output timing thereby to change the timing to output the test signal.

The output control section 30 controls the plurality of drivers 26 to output a plurality of measurement signals respectively in a calibration operation. The output control section 30 may, for example, supply each signal generating section 24 with data that designates a waveform pattern and an output timing. This enables each driver 26 to output a measurement signal having the designated waveform pattern at the designated timing.

Further, the output control section 30 controls the plurality of drivers 26 to output a plurality of measurement signals different from each other. The output control section 30 may, for example, control the plurality of drivers 26 to output a plurality of measurement signals at different timings. Further, the output control section 30 may, for example, control the plurality of drivers 26 to output a plurality of measurement signals having different frequencies from each other. The output control section 30 may, for example, control the plurality of drivers 26 to output a plurality of measurement signals having different code patterns from each other.

The combining section 32 receives, in the calibration operation, the plurality of measurement signals from the plurality of transmission paths, through which signals are transmitted from the plurality of drivers 26 to the device under test. Then, the combining section 32 outputs a combination signal obtained by combining the plurality of measurement signals. The combining section 32 may, for example, output a combination signal obtained by adding the plurality of measurement signals.

For example, the combining section 32 may be provided on a dummy device 40 which is, instead of the device under test, mounted on the performance board 14 in the calibration operation. In this case, the combining section 32 receives the plurality of measurement signals from a plurality of signal output terminals of the performance board 14, which are the interfaces to the device under test. Then, the combining section 32 supplies the combination signal obtained by combining the plurality of measurement signals to the calculating section 34 through a signal line.

The calculating section 34 calculates the skew of each of the plurality of measurement signals output from the plurality of drivers 26 respectively, based on the combination signal, in the calibration operation. That is, the calculating section 34 calculates, based on the combination signal, a delay time indicating how long the measurement signal has been delayed from the reference timing at the point on the transmission path where the combining section 32 acquires the measurement signal, for each of the plurality of measurement signals.

For example, the calculating section 34 extracts the signal component corresponding to each of the plurality of measurement signals from the combination signal. The calculating section 34 extracts a plurality of signal components from the combination signal by, for example, time division, frequency division, or division according to the code pattern. Then, the calculating section 34 detects the phase (phase difference with respect to the reference phase) of each of the plurality of extracted signal components, and calculates a delay time corresponding to the detected phase as a skew.

The setting section 36 sets the timing to output a signal which is to be output from each of the plurality of drivers 26, according to the skew calculated by the calculating section 34. To be more specific, the setting section 36 sets the skew adjusting amount for each of the plurality of adjusting sections 28, based on the skew of the measurement signal output from the corresponding driver 26 in the calibration operation. The setting section 36 may, for example, set the skew adjusting amount for each of the plurality of adjusting sections 28, such that the phases of a plurality of test signals, which are set to be output at the same timing, coincide with each other at predetermined points on the transmission paths (for example, at input terminals of the device under test).

The test apparatus 10 as described above can measure the skews of a plurality of signals collectively. Since the test apparatus 10 does not have to measure the skew of each of the plurality of signals individually, the time taken to measure the skews can be shortened.

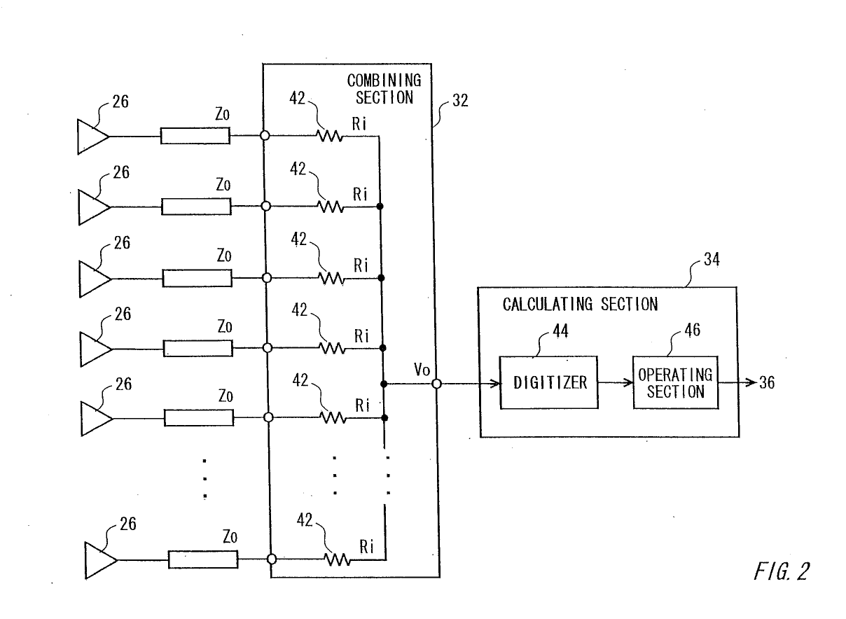

FIG. 2 shows one example of the configuration of the combining section 32 and one example of the configuration of the calculating section 34, together with the plurality of drivers 26. The combining section 32 may, for example, include a plurality of resistors 42.

The plurality of resistors 42 are provided in correspondence with the plurality of channels. The plurality of resistors 42 may, for example, have the same resistance with each other.

Each of the plurality of resistors 42 has its one terminal connected to the transmission path of the corresponding channel, through which a signal is transmitted from the driver 26 to the device under test. Each of the plurality of resistors 42 may, for example, have its one terminal connected to the signal output terminal of the performance board 14, which signal output terminal is the interface to the device under test.

The plurality of resistors 42 have their other terminals connected to the output terminal of the combining section 32 in common. Such a combining section 32 receives the plurality of measurement signals from the side of the one terminal of the plurality of resistors 42. Then, the combining section 32 outputs the combination signal obtained by combining the voltage values of the plurality of measurement signals from the side of the other terminal of the plurality of resistors 42.

For example, assume that the resistance of each resistor 42 is Ri, the input impedance of the calculating section 34 is Zm, and the number of the plurality of resistors 42 is n (n is an integer equal to or larger than 2). Then, in a case where a voltage Vi is supplied to the one terminal of one resistor 42 and a reference potential (for example, a common potential) is supplied to the one terminal of the other resistors 42, the voltage Vo at the other terminal of the plurality of resistors 42 is represented by the following equation (1).

### [Equation 1]

Vo=Vi×Zm(Ri+Zm×n) (1)

Then, in a case where measurement signals are output simultaneously from the plurality of drivers 26, the combining section 32 outputs a combination signal obtained by adding the voltages supplied to the one terminal of the respective resistors 42. Each resistor 42 may, for example, have the same resistance as the resistance Zo of the transmission path that runs from the driver 26 to the combining section 32. This enables each resistor 42 to terminate the measurement signal output from the corresponding driver 26.

The calculating section 34 may, for example, include a digitizer 44 and an operating section 46. The digitizer 44 digitizes the combination signal output from the combining section 32 by sampling the combination signal at a predetermined sampling frequency. The digitizer 44 may, for example, digitize the combination signal by acquiring the voltage waveform of the combination signal.

The calculating section 34 computes the skew of each of the plurality of measurement signals output from the plurality of drivers 26 based on the data sequence output from the digitizer 44 representing the combination signal. The calculating section 34 may, for example, compute the skew of each of the plurality of measurement signals based on data sequence representing the voltage waveform of the combination signal. Such a calculating section 34 can compute the skew of each of the plurality of measurement signals by digital operation.

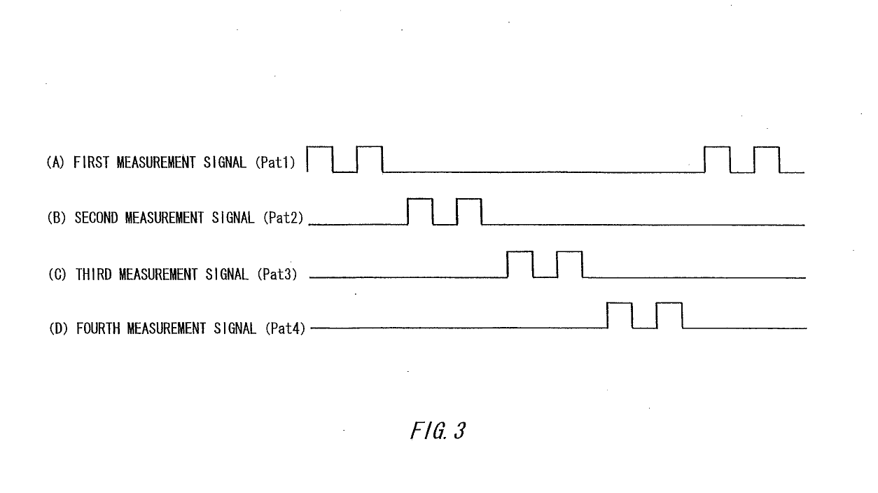

FIG. 3 shows one example of the plurality of measurement signals having initial phases which are different from each other. The output control section 30 may, for example, control the plurality of drivers 26 to output a plurality of measurement signals having initial phases which are different from each other. The output control section 30 may, for example, control a plurality of measurement signals to be output from the plurality of drivers 26 at different times from each other, as shown by (A), (B), (C), and (D) of FIG. 3. Such an output control section 30 can control a plurality of measurement signals to be output, which will not temporally interfere with each other when combined.

In a case where a plurality of measurement signals having initial phases different from each other are output from the plurality of drivers 26, the calculating section 34, for example, extracts a plurality of signal components corresponding to the plurality of measurement signals by doing the time division of the combination signal. Then, the calculating section 34 may calculate the skew based on the phase of each of the plurality of extracted signal components. Such a calculating section 34 can calculate the skew of each measurement signal from the combination signal obtained by combining the plurality of measurement signals having initial phases different from each other.

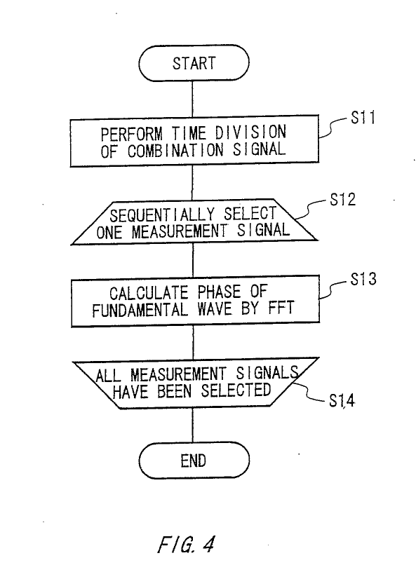

FIG. 4 shows one example of the process flow of the calculating section 34, in a case where a plurality of measurement signals having initial phases different from each other are output. In a case where a plurality of measurement signals having initial phases difference from each other are output from the plurality of drivers 26, the calculating section 34 may, for example, perform the process of step S11 to step S14.

First, the calculating section 34 extracts a plurality of signal components by performing time division of the combination signal to divide it into time domains, in which the measurement signals are estimated to be included respectively (S11). Subsequently, the calculating section 34 sequentially selects each one measurement signal (objective measurement signal) from the plurality of measurement signals and performs the process of step S13 (S12, S14). At step S13, the calculating section 34 performs frequency division of the signal component corresponding to the objective measurement signal by, for example, FFT (Fast Fourier Transform) to compute the phase of its fundamental wave.

Then, when finished with the process of step S13 for all the measurement signals, the calculating section 34 calculates the skew of each measurement signal based on the phase computed at step S13 and gets out of this flow (S14). By performing these steps S11 to S14, the calculating section 34 can calculate the skew of each measurement signal in a case where a plurality of measurement signals having initial phases different from each other are output from the plurality of drivers 26.

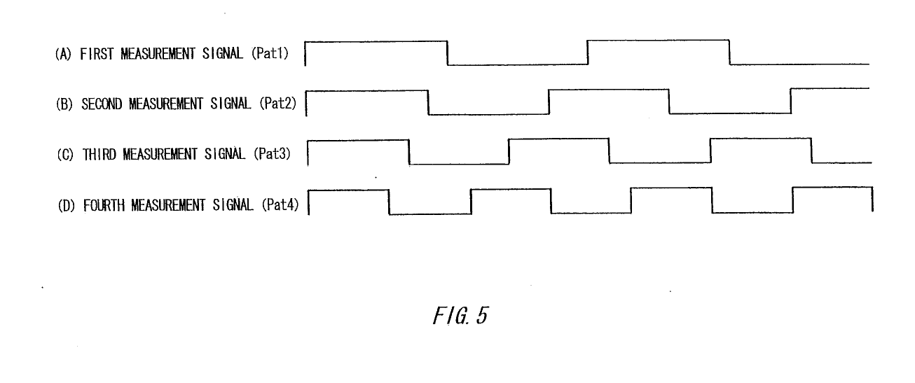

FIG. 5 shows one example of a plurality of measurement signals having frequencies which are different from each other. The output control section 30 may, for example, control the plurality of drivers 26 to output a plurality of measurement signals having frequencies different from each other. The output control section 30 may, for example, control the plurality of drivers 26 to output a plurality of measurement signals having frequencies different from each other as shown by (A), (B), (C), and (D) of FIG. 5. Such an output control section 30 can control a plurality of measurement signals to be output, which will not have their frequencies interfere with each other when combined.

Then, when the plurality of measurement signals having frequencies different from each other are output from the plurality of drivers 26, the calculating section 34, for example, performs frequency division of the combination signal and extracts a plurality of signal components corresponding to the plurality of measurement signals. Then, the calculating section 34 may calculate the skew based on the phase of each of the plurality of extracted signal components. Such a calculating section 34 can calculate the skew of each measurement signal from the combination signal obtained by combining the plurality of measurement signals having frequencies different from each other.

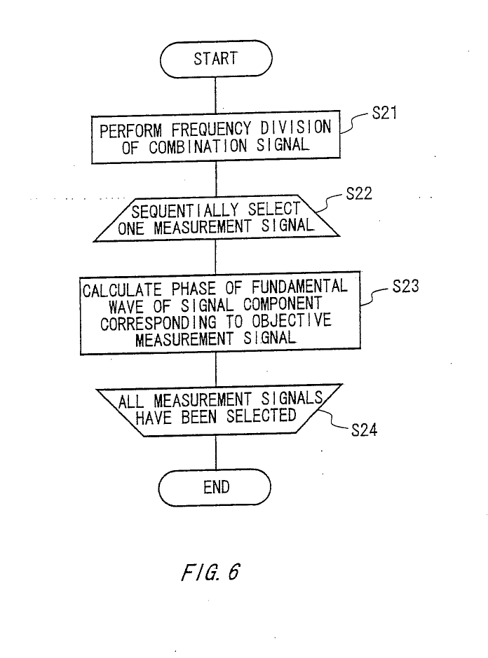

FIG. 6 shows one example of the process flow of the calculating section 34 in a case where a plurality of measurement signals having frequencies different from each other are output. In a case where a plurality of measurement signals having frequencies different from each other are output from the plurality of drivers 26, the calculating section 34 may, for example, perform the process of step S21 to step S24.

First, the calculating section 34 extracts a plurality of signal components by performing frequency division of the combination signal to divide it according to frequency ranges, in which the measurement signals are included respectively (S21). The calculating section 34 may, for example, perform the frequency division of the combination signal by FFT.

Then, the calculating section 34 sequentially selects each one measurement signal (objective measurement signal) from the plurality of measurement signals to perform the process of step S23 (S22, S24). At step S23, the calculating section 34 calculates the phase of the fundamental wave of the signal component corresponding to the objective measurement signal.

Then, when finished with the process of step S23 for all the measurement signals, the calculating section 34 calculates the skew of each measurement signal based on the phase calculated at step S23, and terminates this flow (S24). By performing these steps S21 to S24, the calculating section 34 can calculate the skew of each measurement signal in a case where a plurality of measurement signals having frequencies different from each other are output from the plurality of drivers 26.

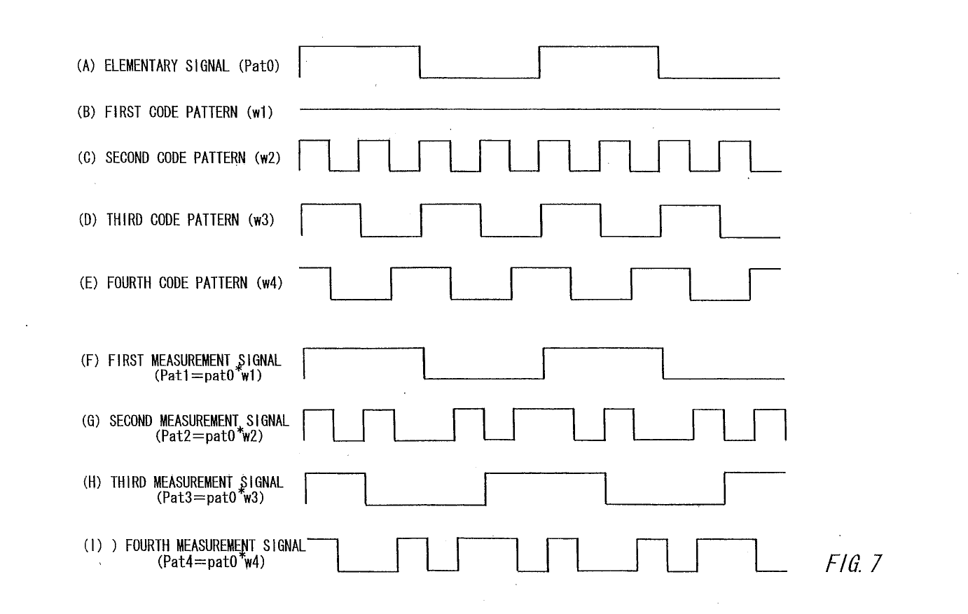

FIG. 7 shows one example of a plurality of measurement signals having code patterns which are different from each other. The output control section 30 may, for example, control the plurality of drivers 26 to output a plurality of measurement signals having code patterns different from each other.

The output control section 30 may, for example, control the plurality of drivers 26 to output a plurality of measurement signals as shown by (F), (G), (H), and (I) of FIG. 5. That is, the output control section 30 may, for example, control the plurality of drivers 26 to output a plurality of measurement signals obtained by multiplying an elementary signal as shown by (A) of FIG. 5 by code patterns shown by (B) to (E) of FIG. 5, which are different from each other. Such an output control section 30 can control a plurality of measurement signals to be output, which will not have their codes interfere with each other when combined.

In a case where a plurality of measurement signals having code patterns different from each other are output from the plurality of drivers 26, the calculating section 34, for example, extracts a plurality of signal components having a plurality of code patterns corresponding to the plurality of measurement signals from the combination signal. Then, the calculating section 34 may calculate the skew based on the phase of each of the plurality of extracted signal components. Such a calculating section 34 can calculate the skew of each measurement signal from the combination signal obtained by combining a plurality of measurement signals having code patterns different from each other.

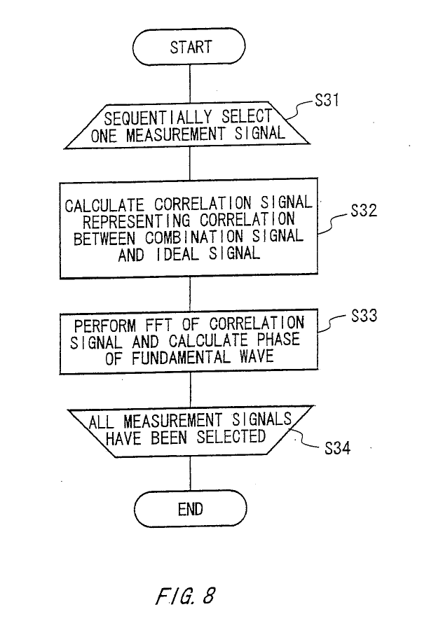

FIG. 8 shows a first example of the process flow of the calculating section 34 in a case where a plurality of measurement signals having code patterns different from each other are output. In a case where a plurality of measurement signals having code patterns different from each other are output from the plurality of drivers 26, the calculating section 34 may, for example, perform the process of step S31 to step S34.

First, the calculating section 34 sequentially selects each one measurement signal (objective measurement signal) from the plurality of measurement signals and performs the processes of step S32 and step S33 (S31, S34). At step S32, the calculating section 34 computes a correlation signal representing the correlation between the combination signal and an ideal signal representing the ideal waveform of the objective measurement signal. Then, at step S33, the calculating section 34 performs frequency division of the correlation signal by, for example, FFT, and calculates the phase of its fundamental wave.

Then, when finished with the processes of steps S32 and S33 for all the measurement signals, the calculating section 34 calculates the skew of each measurement signal based on the phase calculated at step S33, and terminates this flow (S34). By performing these steps S31 to S34, the calculating section 34 can calculate the skew of each measurement signal in a case where a plurality of measurement signals having code patterns different from each other are output from the plurality of drivers 26.

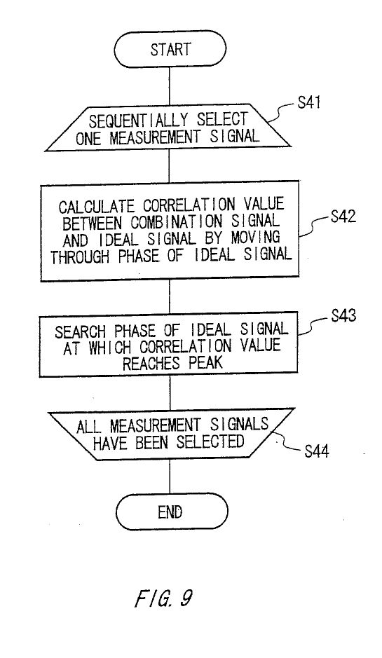

FIG. 9 shows a second example of the process flow of the calculating section 34 in a case where a plurality of measurement signals having code patterns different from each other are output. In a case where a plurality of measurement signals having code patterns different from each other are output from the plurality of drivers 26, the calculating section 34 may, for example, perform the process from step S41 to step S44.

First, the calculating section 34 sequentially selects each one measurement signal (objective measurement signal) from the plurality of measurement signals, and performs the processes of step S42 and step S43 (S41, S44). At step S42, the calculating section 34 calculates a correlation value indicating the correlation between the combination signal and an ideal signal representing the ideal waveform of the objective measurement signal, by moving through the phase of the ideal signal. Note that the correlation value is a value obtained by multiplying a sample value of the combination signal and a sample value of the ideal signal set to have a predetermined phase, which sample values are sampled at the same timing (at the same sampling position), and accumulating the obtained product for one cycle.

Then, at step S43, the calculating section 34 searches and detects the phase of the ideal signal at which the correlation value reaches its peak from the calculation result at step S42. Then, when finished with the processes of steps S42 and S43 for all the measurement signals, the calculating section 34 calculates the skew of each measurement signal based on the phase detected at step S43, and terminates this flow (S44). By performing these steps S41 to S44, the calculating section 34 can calculate the skew of each measurement signal in a case where a plurality of measurement signals having code patterns different from each other are output from the plurality of drivers 26.

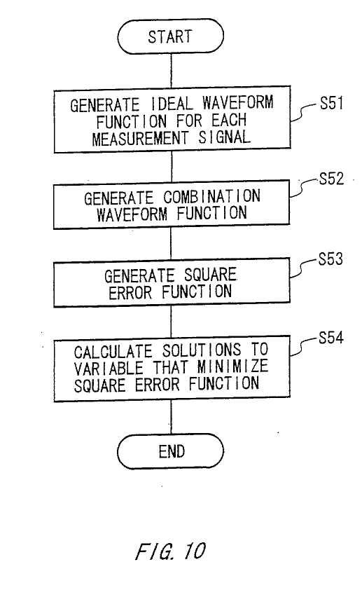

FIG. 10 shows a third example of the process flow of the calculating section 34 in a case where a plurality of measurement signals having code patterns different from each other are output. In a case where a plurality of measurement signals having code patterns different from each other are output from the plurality of drivers 26, the calculating section 34 may, for example, perform the process of step S51 to step S54.

First, the calculating section 34 generates a function (ideal waveform function) representing the ideal waveform of each of the plurality of measurement signals (S51). The ideal waveform function includes a delay time as a variable.

Next, the calculating section 34 generates an ideal combination function obtained by combining the plurality of ideal waveform functions generated at step S51 (S52). Then, the calculating section 34 generates a function (square error function) representing a square error between the combination signal and the ideal combination function (S53). The calculating section 34 may, for example, generate a square error function _{ε}(t)² represented by the following equation (2).

### [Equation 2]

$${ɛ ( t )}^{2} = {\sum }_{k = 1}^{M} {\vert Z ( k ) - \{ {\sum }_{t = 1}^{n} {R}_{i} ( k + Δ {t}_{i} ) \} \vert}^{2} \qquad ( 2 )$$

In the equation (2), M represents the number of points sampled from the combination signal. n represents the number (channel number) of measurement signals combined in the combination signal. Ri(k+Δti) represents the ideal waveform function corresponding to the i-th measurement signal. Δti represents a delay time (variable) included in the i-th measurement signal. Z(k) represents the combination signal.

Then, the calculating section 34 computes a plurality of solutions to the variable (Δti=delay time) that minimize the square error function _{ε}(t)² (S54). The calculating section 34 may, for example, derive a partially-differentiated function obtained by partially differentiating the square error function _{ε}(t)² by each value of the variable Δti, and obtain a plurality of solutions to the variable Δti that satisfy the condition that the partially-differentiated function=0.

Then, the calculating section 34 calculates the skew of each measurement signal based on each of the obtained solutions Δti to the variable, and terminates this flow (S54). By performing these steps S51 to S54, the calculating section 34 can calculate the skew of each measurement signal in a case where a plurality of measurement signals having code patterns different from each other are output from the plurality of drivers 26.

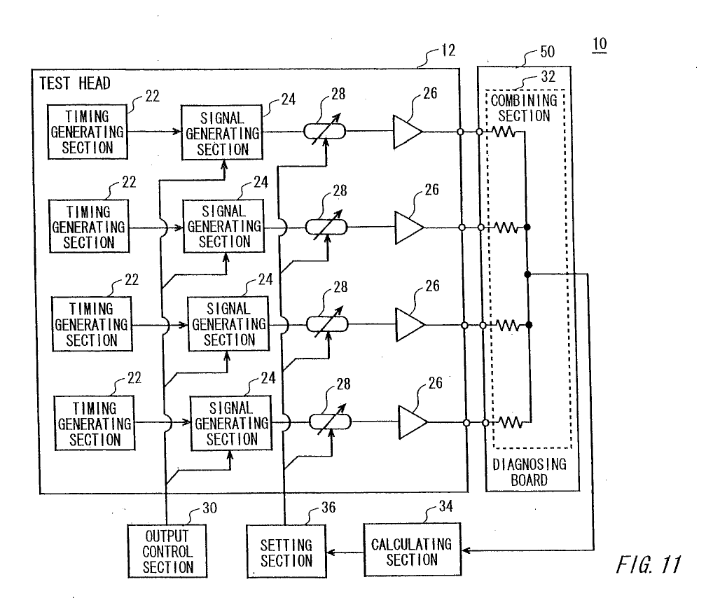

FIG. 11 shows the configuration of the test apparatus 10 according to a first modification of the present embodiment. Since the test apparatus 10 according to the present modification has generally the same configuration and functions as those of the test apparatus 10 shown in FIG. 1, those members that have generally the same configuration and functions will be denoted by the same reference numerals in the drawing, and explanation thereof will be omitted except any difference.

The test apparatus 10 according to the present modification may have not the performance board 14 but a diagnosing board 50 attached on the test head 12 in a calibration operation. In this case, the combining section 32 is provided on the diagnosing board 50, and receives a plurality of measurement signals from a plurality of signal output terminals of the test head 12, which signal output terminals are the interfaces to the performance board 14.

Then, the combining section 32 supplies a combination signal obtained by combining the plurality of measurement signals to the calculating section 34. The test apparatus 10 according to the present modification as above can measure the skews of the respective measurement signals at the plurality of signal output terminals of the test head 12 to the performance board 14.

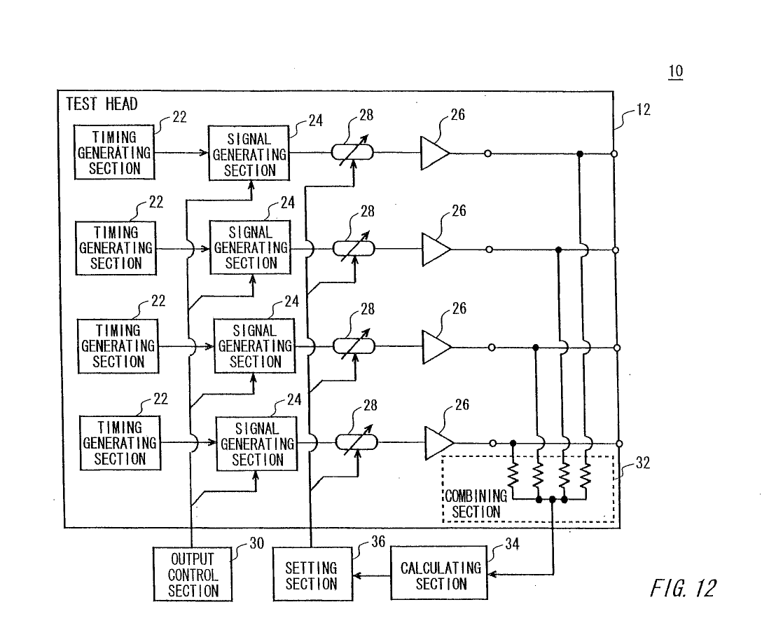

FIG. 12 shows the configuration of the test apparatus 10 according to a second modification of the present embodiment. Since the test apparatus 10 according to the present modification has generally the same configuration and functions as those of the test apparatus 10 shown in FIG. 1, those members that have generally the same configuration and functions will be denoted by the same reference numerals in the drawing, and explanation thereof will be omitted except any difference.

The test apparatus 10 according to the present modification is provided with the combining section 32 inside the test head 12. In this case, the combining section 32 receives a plurality of measurement signals from the signal output terminals of the plurality of drivers 26.

Then, the combining section 32 supplies a combination signal obtained by combining the plurality of measurement signals to the calculating section 34. The test apparatus 10 according to the present modification as above can measure the skew of each measurement signal at the output terminal of the driver 26.

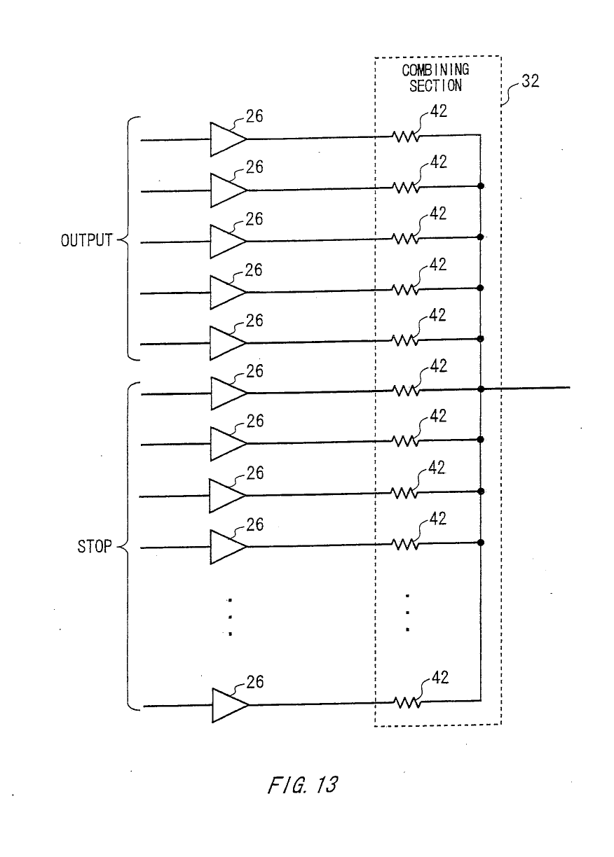

FIG. 13 shows the configuration of the test apparatus 10 according to a third modification of the present embodiment. Since the test apparatus 10 according to the present modification has generally the same configuration and functions as those of the test apparatus 10 shown in FIG. 1, those members that have generally the same configuration and functions will be denoted by the same reference numerals in the drawing, and explanation thereof will be omitted except any reference.

The output control section 30 according to the present modification may control signals to be output from two or more selected drivers 26 of the plurality of drivers 26 which are to output a plurality of measurement signals to be combined by the combining section 32. That is, the output control section 30 may control some drivers 26 of the plurality of drivers 26 to which the combining section 32 is connected to output measurement signals, and may not have to control the other drivers 26 to output measurement signals. The output control section 30 may, for example, control the other drivers 26 that are not controlled to output measurement signals to output a reference voltage (for example, a common voltage). Then, the calculating section 34 calculates the skews of the measurement signals output from the selected two or more drivers 26 based on a combination signal generated by the combining section 32.

The test apparatus 10 having this configuration can select a plurality of measurement signals from which skews should be measured, with no need for switching or the like of the signal lines. This enables the test apparatus 10 to precisely measure the skews. Note that the test apparatus 10 may be provided with a plurality of relays which connect the drivers 26, which are to output measurement signals from which skews should be measured, to the combining section 32, and do not connect the drivers 26, which are to output measurement signals whose skews need not be measured, to the combining section 32.

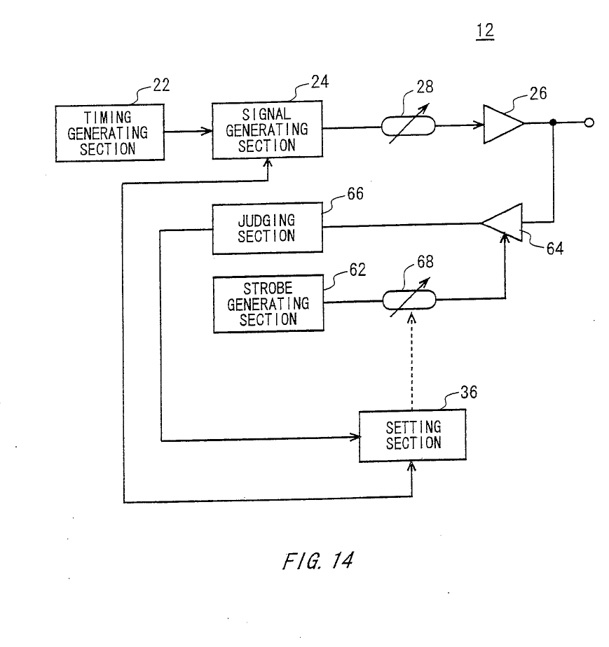

FIG. 14 shows the configuration of the test apparatus 10 according to a fourth modification of the present embodiment. Since the test apparatus 10 according to the present modification has generally the same configuration and functions as those of the test apparatus 10 shown in FIG. 1, those members that have generally the same configuration and functions will be denoted by the same reference numerals in the drawing, and explanation thereof will be omitted except any differences.

The test apparatus 10 according to the present modification may further include a strobe generating section 62, a comparator 64, a judging section 66, and a strobe adjusting section 68, which are accommodated in the test head 12 in correspondence with each of the plurality of channels.

The strobe generating section 62 generates a strobe signal indicating the timing to acquire a response signal output from a device under test. The comparator 64 acquires the logical value of the response signal output from the device under test at the timing indicated by the strobe signal output from the strobe generating section 62 of the corresponding channel. Further, the comparator 64 has its input terminal wired so as to be common to the output terminal of the driver 26 of the corresponding channel. The judging section 66 judges whether or not the logical value acquired by the comparator 64 of the corresponding channel matches an expectation value.

The strobe adjusting section 68 has a strobe adjusting amount set by the setting section 36. The strobe adjusting section 68 changes (delays or accelerates) the timing to acquire the logical value of the corresponding channel from a designated timing by a time duration corresponding to the strobe adjusting amount. The strobe adjusting section 68 may, for example, delay the strobe signal by a time duration corresponding to the strobe adjusting amount, thereby to change the timing of the strobe signal.

The setting section 36 sets the acquisition timing at which the comparator 64 acquires the response signal. The setting section 36, for example, controls the driver 26 to output a signal having a predetermined waveform, after the skew adjustment for the signal to be output from the driver 26 is completed. Then, the setting section 36 sets the strobe adjusting amount such that the signal having the predetermined waveform output from the driver 26 is acquired by the comparator 64 of the corresponding channel at an intended timing. Such a test apparatus 10 can adjust the timings at which the plurality of comparators 64 acquire response signals, as well as adjusting the skews of the plurality of drivers 26.

Further, the test apparatus 10 may measure the skews of the plurality of drivers 26 as separated as skews with respect to rising edges and skews with respect to trailing edges. The test apparatus 10 may, for example, have the calculating section 34 acquire a plurality of measurement signals output from the plurality of drivers 26 as rising edge portions and trailing edge portions separated from each other and measure the phase for each of them. Hence, the test apparatus 10 can test the device under test with high precision even in a case where delays of different amounts occur at the rising edges and trailing edges through the transmission paths.

One aspect of the present invention has been explained using the embodiment, but the technical scope of the present invention is not limited to the scope of disclosure of the above-described embodiment. Various modifications or alterations can be made upon the above-described embodiment. It is obvious from the statements of the claims that embodiments upon which such modifications or alterations are made can also be included in the technical scope of the present invention.

What is claimed is:

1. A test apparatus for testing a device under test, comprising:
a plurality of drivers which output signals to the device under test;
an output control section which controls the plurality of drivers to output a plurality of signals respectively;
a calculating section which calculates skews of the plurality of signals output from the plurality of drivers respectively, based on a combination signal obtained by combining the plurality of signals; and
an adjusting section which adjusts timings to output signals to be output from the plurality of drivers respectively, based on the skews.

2. The test apparatus according to claim 1,
wherein the output control section controls the plurality of drivers to output a plurality of signals having different initial phases from each other, and
the calculating section extracts a plurality of signal components corresponding to the plurality of signals by performing time division of the combination signal, and calculates the skews based on phases of the plurality of extracted signal components.

3. The test apparatus according to claim 1,
wherein the output control section controls the plurality of drivers to output the plurality of signals having different frequencies from each other, and
the calculating section extracts a plurality of signal components corresponding to the plurality of signals by performing frequency division of the combination signal, and calculates the skews based on phases of the plurality of extracted signal components.

4. The test apparatus according to claim 1,
wherein the output control section controls the plurality of drivers to output the plurality of signals having different code patterns from each other, and
the calculating section extracts a plurality of signal components having a plurality of code patterns corresponding to the plurality of signals from the combination signal, and calculates the skews based on phases of the plurality of extracted signal components.

5. The test apparatus according to claim 1, further comprising a combining section which receives the plurality of signals from a plurality of transmission paths through which signals are transmitted from the plurality of drivers to the device under test, and outputs the combination signal.

6. The test apparatus according to claim 5,
wherein the combining section includes a plurality of resistors which have their terminals at one side connected to the plurality of transmission paths respectively, and have their terminals at the other side connected to be common, and
the calculating section acquires a voltage waveform of the combination signal from the terminals at the other side of the plurality of resistors, and calculates the skews of the plurality of signals based on the acquired voltage waveform of the combination signal.

7. The test apparatus according to claim 5,
wherein the combining section is provided on a dummy device which is, instead of the device under test, mounted on a performance board, and receives the plurality of signals from a plurality of signal output terminals of the performance board, the signal output terminals being interfaces to the device under test.

8. The test apparatus according to claim 5,
wherein the combining section is provided on a diagnosing board which is, instead of a performance board on which the device under test is mounted, attached to a test head, and receives the plurality of signals from a plurality of signal output terminals of the test head, the signal output terminals being interfaces to the performance board.

9. The test apparatus according to claim 5,
wherein the combining section is provided on a test head, and receives the plurality of signals from signal output terminals of the plurality of drivers.

10. The test apparatus according to claim 5,
wherein the output control section controls the signals to be output from selected two or more drivers of the plurality of drivers which are to output the plurality of signals to be combined by the combining section, and
the calculating section calculates skews of two or more signals output from the selected two or more drivers, based on the combination signal.

11. A skew measuring apparatus for measuring skews of a plurality of signals output from a plurality of drivers, comprising:
an output control section which controls the plurality of drivers to output a plurality of signals respectively; and
a calculating section which calculates skews of the plurality of signals output from the plurality of drivers respectively, based on a combination signal obtained by combining the plurality of signals.

12. A device which is, instead of a device under test, mounted on a performance board, in measuring skews of a plurality of signals output from a plurality of drivers provided in a test apparatus for testing the device under test, the device comprising
a combining section which receives and combines together the plurality of signals which are from a plurality of signal output terminals of the performance board, the signal output terminals being interfaces to the device under test that exist on a plurality of transmission paths through which signals are transmitted from the plurality of drivers to the device under test.

13. A board which is, instead of a performance board on which a device under test is mounted, attached to a test head, in measuring skews of a plurality of signals output from a plurality of drivers provided in a test apparatus for testing the device under test, the board comprising
a combining section which receives and combines together the plurality of signals which are from a plurality of signal output terminals of the test head, the signal output terminals being interfaces to the performance board that exist on a plurality of transmission paths through which signals are transmitted from the plurality of drivers to the device under test.

14. The skew measuring apparatus according to claim 11,
wherein the output control section controls the plurality of drivers to output a plurality of signals having different initial phases from each other, and
the calculating section extracts a plurality of signal components corresponding to the plurality of signals by performing time division of the combination signal, and calculates the skews based on phases of the plurality of extracted signal components.

15. The skew measuring apparatus according to claim 11,
wherein the output control section controls the plurality of drivers to output the plurality of signals having different frequencies from each other, and
the calculating section extracts a plurality of signal components corresponding to the plurality of signals by performing frequency division of the combination signal, and calculates the skews based on phases of the plurality of extracted signal components.

16. The skew measuring apparatus according to claim 11,
wherein the output control section controls the plurality of drivers to output the plurality of signals having different code patterns from each other, and
the calculating section extracts a plurality of signal components having a plurality of code patterns corresponding to the plurality of signals from the combination signal, and calculates the skews based on phases of the plurality of extracted signal components.

17. The skew measuring apparatus according to claim 11, further comprising a combining section which receives the plurality of signals from a plurality of transmission paths through which signals are transmitted from the plurality of drivers to a device under test, and outputs the combination signal.
